(19) United States
(12) Patent Application Publication
(10) Pub. No.: US 2024/0047832 A1
(43) Pub. Date: Feb. 8, 2024

(54) ELECTROCHEMICAL CELLS AND ELECTROCHEMICAL CELL STACKS WITH SERIES CONNECTIONS, AND METHODS OF PRODUCING, OPERATING, AND MONITORING THE SAME

(71) Applicant: 24M Technologies, Inc., Cambridge, MA (US)

(72) Inventors: Chad Alan HARTZOG, Columbus, IN (US); Mark YOUNG, Lapel, IN (US); Kenneth Douglas COBB, Nobleville, IN (US); Junzheng CHEN, Concord, MA (US)

(21) Appl. No.: 18/228,921

(22) Filed: Aug. 1, 2023

Related U.S. Application Data
(60) Provisional application No. 63/394,341, filed on Aug. 2, 2022.

(51) Int. Cl. H01M 50/503; H01M 50/51; H01M 50/209; H01M 50/264

(52) U.S. Cl. CPC H01M 50/503; H01M 50/51; H01M 50/209; H01M 50/264

(57) ABSTRACT

Embodiments described herein relate to electrochemical cells and multicells. A multicell can include a cell packaging that includes two or more electrochemical cells connected in series internal to the cell packaging. In some aspects, an apparatus includes a plurality of electrochemical cell stacks each including a plurality of electrochemical cells connected in series, a first electrically conductive plate including a first section and a second section, and a second electrically conductive plate. The first section of the first electrically conductive plate is in contact with a first terminal end of a first electrochemical cell stack from the plurality of electrochemical cell stacks. The second section of the first electrically conductive plate is in contact with a first terminal end of a second electrochemical cell stack from the plurality of electrochemical cell stacks.

### CROSS-REFERENCE TO RELATED APPLICATIONS

This application claims priority to and the benefit of U.S. Provisional Patent Application No. 63/394,341 entitled, “Electrochemical Cells and Electrochemical Cell Stacks with Series Connections and Methods of Producing, Operating, and Monitoring the Same,” filed Aug. 2, 2022; the disclosure of which is incorporated herein by reference in its entirety.

### TECHNICAL FIELD

Embodiments described herein relate to electrochemical cells and multicells arranged in stacks as part of a module build, and methods of producing and operating the same.

### BACKGROUND

Electrochemical cell stacks can be formed by disposing multiple such electrochemical cells on top of each other. Existing methods of arranging electrochemical cells in stacks and connecting them in series are utilized in low power battery applications such as in consumer portable electronics (e.g., lithium coin cells in laser pointers, alkaline cells in flashlights, etc.). In such systems, individual electrochemical cell casings may serve as electrical connection points between electrochemical cells in a stack. However, it may be desirable to manufacture electrochemical cell stacks that can achieve a high total voltage for use in high power applications such as in electric vehicle batteries or in solar energy systems. Existing electrochemical cell systems are not amenable to produce electrochemical cell stacks that can achieve a high total voltage that remain compact in size, relatively easy to transport, and convenient and low-cost to manufacture.

### SUMMARY

Embodiments described herein relate to electrochemical cells and multicells. A multicell can include a cell packaging that includes two or more electrochemical cells connected in series internal to the cell packaging. In some aspects, an apparatus includes a plurality of electrochemical cell stacks each including a plurality of electrochemical cells connected in series, a first electrically conductive plate including a first section and a second section, and a second electrically conductive plate. The first section of the first electrically conductive plate is in contact with a first terminal end of a first electrochemical cell stack from the plurality of electrochemical cell stacks. The second section of the first electrically conductive plate is in contact with a first terminal end of a second electrochemical cell stack from the plurality of electrochemical cell stacks. The second electrically conductive plate is in contact with a second terminal end of the first electrochemical stack. In some embodiments, a first section of the second electrically conductive plate is in contact with the second terminal end of the first stack and the second electrically conductive plate includes a second section in contact with a second terminal end of the second electrochemical cell stack.

In some aspects, an apparatus includes a plurality of electrochemical cell stacks, each electrochemical cell stack from the plurality of electrochemical cell stacks including a plurality of electrochemical cells connected in series, a first electrically conductive plate configured to electrically connect a first pair of electrochemical cell stacks from the plurality of electrochemical cell stacks in series, and a second electrically conductive plate configured to electrically connect a second pair of electrochemical cell stacks from the plurality of electrochemical cell stacks in series. In some embodiments, the first pair of electrochemical cell stacks has one electrochemical cell stack in common with the second pair of electrochemical cell stacks.

In some aspects, the apparatus includes a first stack of electrochemical cells connected in series, a second stack of electrochemical cells connected in series, and an electrically conductive plate contacting a first electrochemical cell at a terminal end of the first stack of electrochemical cells and a second electrochemical cell at a terminal end of the second stack of electrochemical cells.

### BRIEF DESCRIPTION OF THE DRAWINGS

FIG. 1 is a block diagram of a collection of electrochemical cell stacks, according to an embodiment.

FIG. 2 is a block diagram of an electrochemical cell stack, according to an embodiment.

FIGS. 3A-3D are illustrations of an electrochemical cell stack, according to an embodiment.

FIGS. 4A-4B are illustrations of an electrochemical cell stack, according to an embodiment.

FIGS. 5A-5I are illustrations of an electrochemical cell stack and a method of production thereof, according to an embodiment.

FIGS. 6A-6B show collections of electrochemical cell stacks, according to an embodiment.

FIG. 7 is a schematic flow chart of a method of producing a collection of electrochemical cell stacks, according to an embodiment.

### DETAILED DESCRIPTION

Embodiments described herein describe production of electrochemical cells as part of a module build. High voltage cells, modules and packs can be built and then the cells can be formed in higher voltage system blocks, thereby reducing steps in the manufacturing process as well as components required in the overall system. Modules can be assembled and sent to a formation area, where connected in series to achieve a higher total voltage (e.g., 500 V). However, any intermediate voltage may be selected based on building, safety, process, grid, or battery formation-test machine needs. Limitations on voltage can also be based on available DC/DC or AC/DC conversion technologies based on cost or conversion efficiencies. A control system for bypassing energy (charge, discharge both) around modules, cells, or packs can ensure safe operation, preventing overcharge and allowing for full formation of each cell. A safety system can monitor temperature, current, and/or voltage to prevent cell damage and thermal runaway due to over-temperature, over-charge or over-discharge. Methods relating to producing electrochemical cells connected in series in a single pouch are described in U.S. Patent Publication No. 2022/0278427 (“the '427 publication”), filed May 13, 2022 and titled “Electrochemical Cells Connected in Series in a Single Pouch and Method of Making the Same,” the entire disclosure of which is hereby incorporated by reference.

Existing methods of arranging electrochemical cells in stacks and connecting the electrochemical cells included in a stack in series are utilized in low power battery applications such as in consumer portable electronics (e.g., lithium coin cells in laser pointers, alkaline cells in flashlights, etc.). Existing methods include either (1) disposing an electrochemical cell in a casing and stacking such casings on each other, the casings serving as electrical connection points between electrochemical cells in a stack or (2) arranging a plurality of electrochemical cells in a stack, connecting the plurality of electrochemical cells in series, and disposing the plurality of electrochemical cells in a single pouch. However, existing electrochemical cell systems do not often achieve a high total voltage while remaining compact in size, relatively easy to transport, and convenient and low-cost to manufacture.

Embodiments described herein relate to systems of electrochemical cells and multicells arranged in stacks as part of a module build, and methods of producing and operating the same. Embodiments described herein may provide one or more benefits including, for example: (1) an ability to achieve a higher total voltage (e.g., 500 V); (2) a reduction of component count at a system level (e.g., elimination of bus bars); (3) a reduction of manufacturing steps and components required in the system; (4) an elimination of a requirement for welding equipment (e.g., laser or ultrasonic welders); (5) a potential for the system to be assembled in the field; (6) easy replacement of cells and/or strings in the event of a failed cell and/or string in the absence of permanent welded connections; (7) an ease of transportability of the system; (8) a simple design that reduces manufacturing time and cost; and (9) an ability to implement flexible voltage levels.

High voltage cells, modules, and packs are useful in high power applications such as in electric vehicle batteries and solar energy systems. High voltage cells provide benefits such as (1) a higher charge and discharge efficiency than low voltage batteries, thereby allowing support of higher load demands; (2) a high energy density; and (3) improved performance of the device, system, appliance, or machine that is being powered.

In some embodiments, electrodes described herein can include conventional solid electrodes. In some embodiments, the solid electrodes can include binders. In some embodiments, electrodes described herein can include semi-solid electrodes. Semi-solid electrodes described herein can be made: (i) thicker (e.g., greater than 100 μm-up to 2,000 μm or even greater) than conventional electrodes due to the reduced tortuosity and higher electrical conductivity of the semi-solid electrode, (ii) with higher loadings of active materials, and (iii) with a simplified manufacturing process utilizing less equipment. These relatively thick semi-solid electrodes decrease the volume, mass and cost contributions of inactive components with respect to active components, thereby enhancing the commercial appeal of batteries made with the semi-solid electrodes. In some embodiments, the semi-solid electrodes described herein are binderless and/or do not use binders that are used in conventional battery manufacturing. Instead, the volume of the electrode normally occupied by binders in conventional electrodes, is now occupied by: 1) electrolyte, which has the effect of decreasing tortuosity and increasing the total salt available for ion diffusion, thereby countering the salt depletion effects typical of thick conventional electrodes when used at high rate, 2) active material, which has the effect of increasing the charge capacity of the battery, or 3) conductive additive, which has the effect of increasing the electronic conductivity of the electrode, thereby countering the high internal impedance of thick conventional electrodes. The reduced tortuosity and a higher electronic conductivity of the semi-solid electrodes described herein, results in superior rate capability and charge capacity of electrochemical cells formed from the semi-solid electrodes. Since the semi-solid electrodes described herein, can be made substantially thicker than conventional electrodes, the ratio of active materials (i.e., the semi-solid cathode and/or anode) to inactive materials (i.e., the current collector and separator) can be much higher in a battery formed from electrochemical cell stacks that include semi-solid electrodes relative to a similar battery formed form electrochemical cell stacks that include conventional electrodes. This substantially increases the overall charge capacity and energy density of a battery that includes the semi-solid electrodes described herein.

In some embodiments, the electrode materials described herein can be a flowable semi-solid or condensed liquid composition. In some embodiments, the electrode materials described herein can be binderless or substantially free of binder. A flowable semi-solid electrode can include a suspension of an electrochemically active material (anodic or cathodic particles or particulates), and optionally an electronically conductive material (e.g., carbon) in a non-aqueous liquid electrolyte. Said another way, the active electrode particles and conductive particles are co-suspended in an electrolyte to produce a semi-solid electrode. Examples of battery architectures utilizing semi-solid suspensions are described in International Patent Publication No. WO 2012/024499, entitled “Stationary, Fluid Redox Electrode,” and International Patent Publication No. WO 2012/088442, entitled “Semi-Solid Filled Battery and Method of Manufacture,” the entire disclosures of which are hereby incorporated by reference.

As used in this specification, the singular forms “a,” “an,” and “the” include plural referents unless the context clearly dictates otherwise. Thus, for example, the term “a member” is intended to mean a single member or a combination of members, “a material” is intended to mean one or more materials, or a combination thereof.

The term “substantially” when used in connection with “cylindrical,” “linear,” and/or other geometric relationships is intended to convey that the structure so defined is nominally cylindrical, linear or the like. As one example, a portion of a support member that is described as being “substantially linear” is intended to convey that, although linearity of the portion is desirable, some non-linearity can occur in a “substantially linear” portion. Such non-linearity can result from manufacturing tolerances, or other practical considerations (such as, for example, the pressure or force applied to the support member). Thus, a geometric construction modified by the term “substantially” includes such geometric properties within a tolerance of plus or minus 5% of the stated geometric construction. For example, a “substantially linear” portion is a portion that defines an axis or center line that is within plus or minus 5% of being linear.

As used herein, the term “set” and “plurality” can refer to multiple features or a singular feature with multiple parts. For example, when referring to a set of electrodes, the set of electrodes can be considered as one electrode with multiple portions, or the set of electrodes can be considered as multiple, distinct electrodes. Additionally, for example, when referring to a plurality of electrochemical cells, the plurality of electrochemical cells can be considered as multiple, distinct electrochemical cells or as one electrochemical cell with multiple portions. Thus, a set of portions or a plurality of portions may include multiple portions that are either continuous or discontinuous from each other. A plurality of particles or a plurality of materials can also be fabricated from multiple items that are produced separately and are later joined together (e.g., via mixing, an adhesive, or any suitable method).

As used herein, the term “semi-solid” refers to a material that is a mixture of liquid and solid phases, for example, such as a particle suspension, a slurry, a colloidal suspension, an emulsion, a gel, or a micelle.

As used herein, the terms “energy density” and “volumetric energy density” refer to the amount of energy (e.g., MJ) stored in an electrochemical cell per unit volume (e.g., L) of the materials included for the electrochemical cell to operate such as, the electrodes, the separator, the electrolyte, and the current collectors. Specifically, the materials used for packaging the electrochemical cell are excluded from the calculation of volumetric energy density.

As used herein, the terms “high-capacity materials” or “high-capacity anode materials” refer to materials with irreversible capacities greater than 300 mAh/g that can be incorporated into an electrode in order to facilitate uptake of electroactive species. Examples include tin, tin alloy such as Sn—Fe, tin mono oxide, silicon, silicon alloy such as Si—Co, silicon monoxide, aluminum, aluminum alloy, mono oxide metal (CoO, FeO, etc.) or titanium oxide.

As used herein, the term “composite high-capacity electrode layer” refers to an electrode layer with both a high-capacity material and a traditional anode material, e.g., a silicon-graphite layer.

As used herein, the term “solid high-capacity electrode layer” refers to an electrode layer with a single solid phase high-capacity material, e.g., sputtered silicon, tin, tin alloy such as Sn—Fe, tin mono oxide, silicon, silicon alloy such as Si—Co, silicon monoxide, aluminum, aluminum alloy, mono oxide metal (CoO, FeO, etc.) or titanium oxide.

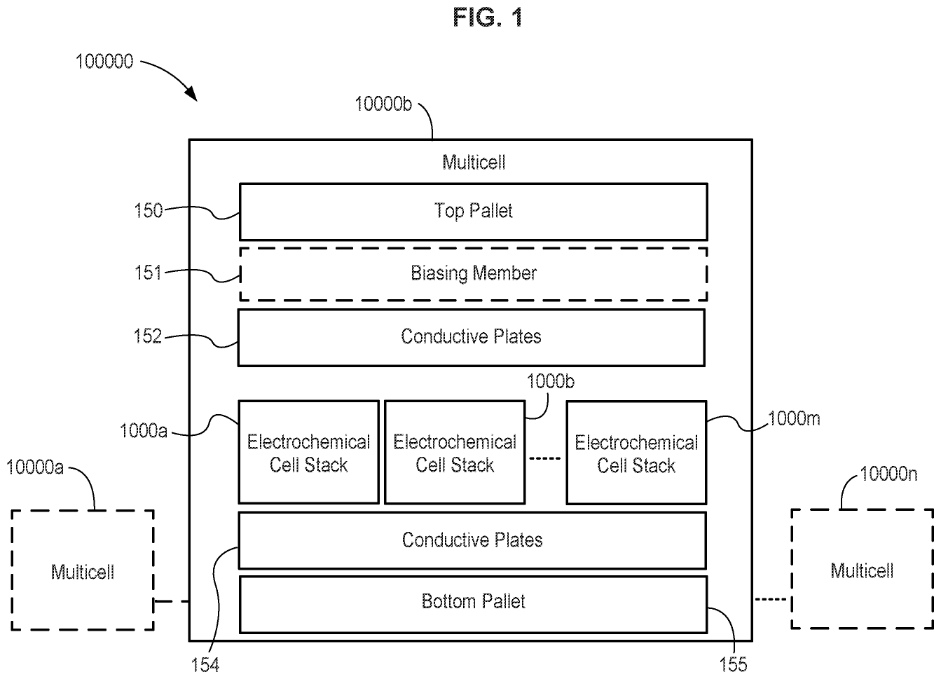

FIG. 1 is a block diagram of an apparatus 100000 including multiple multicells 10000a-10000n (collectively referred to as multicells 10000), according to an embodiment. In some embodiments, the multicells 10000a-10000n may include a plurality of electrochemical cells that are stacked on top of one another to form an electrochemical cell stack 1000a-1000n (hereinafter “stack”). In some embodiments, the plurality of electrochemical cells included in a stack 1000a-1000n can be connected in parallel. In some embodiments, the plurality of electrochemical cells included in a stack 1000a-1000n can be connected in series. Any number of electrochemical cells may be included in a stack. In some embodiments, a number of electrochemical cells in each stack 1000a-1000n may be in a range of about 2 to about 100, inclusive (e.g., about 3, about 4, about 5, about 10, about 15, about 20, about 25, about 30, about 35, about 40, about 45, about 50, about 55, about 60, about 65, about 70, about 75, about 80, about 85, about 90, about 95, or about 100 electrochemical cells, inclusive of all ranges and values therebetween). In some embodiments, an odd number of electrochemical cells may be included in each stack 1000a-n. In some embodiments, an even number of electrochemical cells may be included in each stack 1000a-1000n. The apparatus may include a plurality of stacks (collectively referred to as stacks 1000).

The multicells 10000a-10000n may include a top pallet 150 including a biasing member 151. In some embodiments, the biasing member 151 is a plurality of springs (e.g., helical springs, Belleville springs, lead springs, etc.) integrated into the top pallet 150. In some embodiments, 48 springs are integrated into the top pallet 150. In some embodiments, the top pallet 150 can include at least about 1, at least about 2, at least about 3, at least about 4, at least about 5, at least about 6, at least about 7, at least about 8, at least about 9, at least about 10, at least about 10, at least about at least about 30, at least about 40, at least about 50, at least about 60, at least about 70, at least about 80, at least about 90, at least about 100, at least about 200, at least about 300, at least about 400, at least about 500, at least about 600, at least about 700, at least about 800, or at least about 900 biasing members 151. In some embodiments, the top pallet 150 can include no more than about 1,000, no more than about 900, no more than about 800, no more than about 700, no more than about 600, no more than about 500, no more than about 400, no more than about 300, no more than about 200, no more than about 100, no more than about 90, no more than about 80, no more than about 70, no more than about 60, no more than about 50, no more than about 40, no more than about 30, no more than about 20, no more than about 10, no more than about 9, no more than about 8, no more than about 7, no more than about 6, no more than about 5, no more than about 4, no more than about 3, or no more than about 2 biasing members 151. Combinations of the above-referenced numbers of biasing members 151 are also possible (e.g., at least about 2 and no more than about 1,000 or at least about 30 and no more than about 100), inclusive of all values and ranges therebetween. In some embodiments, the top pallet 150 can include about 1, about 2, about 3, about 4, about 5, about 6, about 7, about 8, about 9, about 10, about 10, about 20, about 30, about 40, about 50, about 60, about 70, about 80, about 90, about 100, about 200, about 300, about 400, about 500, about 600, about 700, about 800, about 900, or about 1,000 biasing members 151.

The biasing member(s) 151 may contact and press one or more electrically conductive plates 152 (hereinafter “conductive plates”) onto the stacks 1000 to provide a pressure. The conductive plates 152 can electrically connect the stacks 1000 in series or in parallel. In some embodiments, the conductive plates 152 can include integrated spring features in place of standalone springs (e.g., stamped dimples or spring fingers). In some embodiments, the conductive plates 152 can be plated for reduced contact resistance and enhanced corrosion resistance. Raised geometry (e.g., dimples) may be used for reduced contact resistance. Conductor pads and springs can be pre-assembled or otherwise held captive in pallets to comprise single assemblies for ease of a system build.

In some embodiments, the top pallet 150 contacts two conductive plates 152. In some embodiments, the multicell 10000 can include at least about 1, at least about 2, at least about 3, at least about 4, at least about 5, at least about 6, at least about 7, at least about 8, at least about 9, at least about 10, at least about 15, at least about 20, at least about 25, at least about 30, at least about at least about 40, or at least about 45 conductive plates 152. In some embodiments, the multicell 10000 can include no more than about 50, no more than about 45, no more than about no more than about 35, no more than about 30, no more than about 25, no more than about 20, no more than about 15, no more than about 10, no more than about 9, no more than about 8, no more than about 7, no more than about 6, no more than about 5, no more than about 4, no more than about 3, or no more than about 2 conductive plates 152. Combinations of the above-referenced numbers of conductive plates 152 are also possible (e.g., at least about 1 and no more than about 50 or at least about 2 and no more than about 30), inclusive of all values and ranges therebetween. In some embodiments, the multicell 10000 can include about 1, about 2, about 3, about 4, about 5, about 6, about 7, about 8, about 9, about 10, about 15, about 20, about 25, about about 35, about 40, about 45, or about 50 conductive plates 152. In some embodiments, all of the conductive plates 152 can contact the top pallet 150 and/or the biasing member 151.

The apparatus 100000 may include a bottom pallet 155. The top pallet 152 and the bottom pallet 155 may be used to align electrochemical cells in each stack 1000a-1000n and provide a means of applying pressure to large electrochemical cell surfaces. In some embodiments, the bottom pallet 155 may include the biasing member(s) 151. In some embodiments, both the top pallet 150 and the bottom pallet 155 may include biasing members 151. In some embodiments, the biasing member(s) 151 may contact and press one or more conductive plates 154 onto the stacks 1000 to provide pressure. The conductive plates 154 can electrically connect the cell stacks 1000 in series or in parallel. In some embodiments, the conductive plates 154 can include integrated spring features in place of standalone springs (e.g., stamped dimples or spring fingers). In some embodiments, the conductive plates 154 can be plated for reduced contact resistance and enhanced corrosion resistance. Raised geometry (e.g., dimples) may be used for reduced contact resistance. Conductor pads and springs can be pre-assembled or otherwise held captive in pallets to comprise single assemblies for ease of a system build.

The bottom pallet 155 may be coupled to conductive plates 154 via system connectors (not shown). The system connectors can protrude to the outside of the bottom pallet 155 via a positive terminal and a negative terminal and may electrically connect a multicell 10000a-n to one or more other multicells 10000a-n. In some embodiments, the multicell 10000 can include at least about 1, at least about 2, at least about 3, at least about 4, at least about 5, at least about 6, at least about 7, at least about 8, at least about 9, at least about 10, at least about 15, at least about 20, at least about at least about 30, at least about 35, at least about 40, or at least about 45 conductive plates 154. In some embodiments, the multicell 10000 can include no more than about 50, no more than about no more than about 40, no more than about 35, no more than about 30, no more than about 25, no more than about 20, no more than about 15, no more than about 10, no more than about 9, no more than about 8, no more than about 7, no more than about 6, no more than about 5, no more than about 4, no more than about 3, or no more than about 2 conductive plates 154. Combinations of the above-referenced numbers of conductive plates 154 are also possible (e.g., at least about 1 and no more than about 50 or at least about 2 and no more than about 30), inclusive of all values and ranges therebetween. In some embodiments, the multicell 10000 can include about 1, about 2, about 3, about 4, about 5, about 6, about 7, about 8, about 9, about 10, about 15, about 20, about about 30, about 35, about 40, about 45, or about 50 conductive plates 154. In some embodiments, all of the conductive plates 154 can contact the bottom pallet 155 and/or the biasing member(s) 151.

The connection between the stacks 1000 and the conductive plates 152, 154 allows current to flow through the stacks 1000. In some embodiments, the current flows from the negative terminal via a first stack 1000a to a first conductive plate 152 contacting the top pallet 150. The current then passes through a second stack 1000b to a conductive plate 154 contacting the bottom pallet 155. The current may then pass through a third stack to a second conductive plate 152, and then through a fourth stack to the positive terminal.

In some embodiments, the multicell 10000a may be electrically connected to one or more other multicells 10000. In some embodiments, the multicell 10000a may be electrically connected to the multicell 10000b via a string connection, the multicell 10000b may be electrically connected to a multicell via a string connection, and so on. In some embodiments the apparatus 100000 can include four multicells 10000. Including a plurality of multicells in the apparatus 100000 allows the apparatus 100000 to achieve a high total voltage for use in high power applications.

In some embodiments, the apparatus 100000 can include at least about 2, at least about 3, at least about 4, at least about 5, at least about 6, at least about 7, at least about 8, at least about 9, at least about 10, at least about 20, at least about 30, at least about 40, at least about 50, at least about 60, at least about 70, at least about 80, at least about 90, at least about 100, at least about 200, at least about 300, at least about 400, at least about 500, at least about 600, at least about 700, at least about 800, or at least about 900 multicells 10000. In some embodiments, the apparatus 100000 can include no more than about 1,000, no more than about 900, no more than about 800, no more than about 700, no more than about 600, no more than about 500, no more than about 400, no more than about 300, no more than about 200, no more than about 100, no more than about no more than about 80, no more than about 70, no more than about 60, no more than about 50, no more than about 40, no more than about 30, no more than about 20, no more than about 10, no more than about 9, no more than about 8, no more than about 7, no more than about 6, no more than about 5, no more than about 4, no more than about 3 multicells 10000. Combinations of the above-referenced numbers of multicells 10000 are also possible (e.g., at least about 2 and no more than about 1,000 or at least about 4 and no more than about 50), inclusive of all values and ranges therebetween. In some embodiments, the apparatus 100000 can include about 2, about 3, about 4, about 5, about 6, about 7, about 8, about 9, about 10, about 20, about 30, about 40, about 50, about about 70, about 80, about 90, about 100, about 200, about 300, about 400, about 500, about 600, about 700, about 800, about 900, or about 1,000 multicells 10000. The string connections can be composed of an electrically conductive material. The apparatus 100000 includes a collective negative terminal and a collective positive terminal for connections to a voltage source.

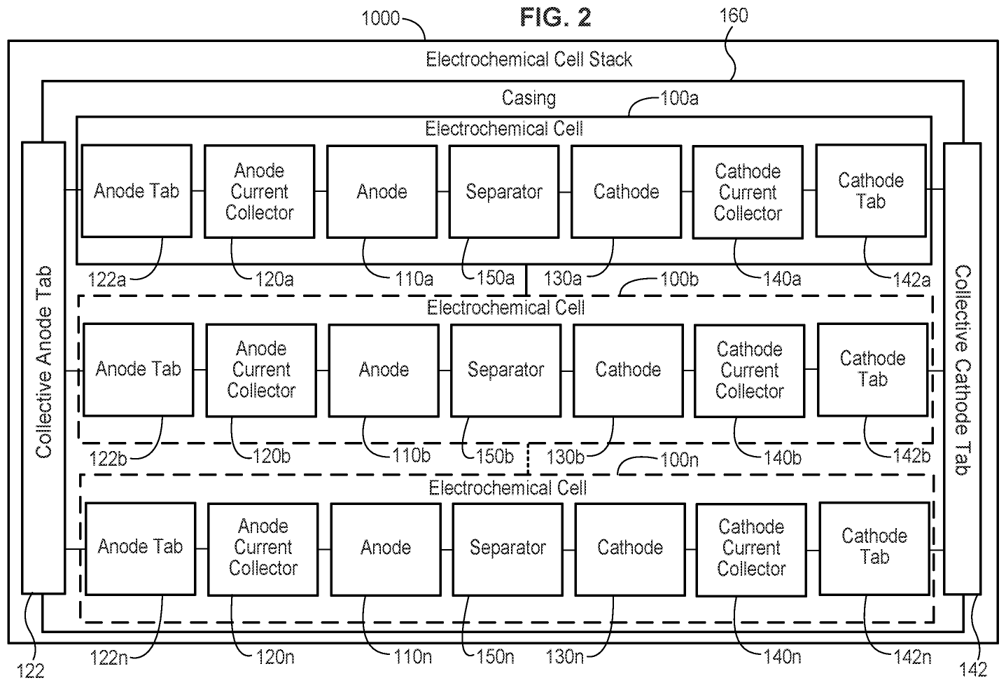

FIG. 2 is a block diagram of an electrochemical cell stack (or a multicell) 1000, according to an embodiment. As shown, the electrochemical cell stack 1000 includes electrochemical cells 100a, 100b, 100n (collectively referred to as electrochemical cells 100). As shown, the electrochemical cells 100 are connected in series. The electrochemical cells 100 include anodes 110a, 110b, 100n (collectively referred to as anodes 110) disposed on anode current collectors 120a, 120b, . . . , 120n (collectively referred to as anode current collectors 120), cathodes 130a, 130b, . . . , 130n (collectively referred to as cathodes 130) disposed on cathode current collectors 140a, 140b, . . . , 140n (collectively referred to as cathode current collectors 140), and separators 150a, 150b, . . . , 150n (collectively referred to as separators 150) disposed between the anodes 110 and the cathodes 130. The anode current collectors 120 include anode tabs 122a, 122b, . . . , 122n, each coupled to a collective anode tab 122. The cathode current collectors 140 include cathode tabs 142a, 142b, . . . , 142n, each coupled to a collective cathode tab 142. As shown, the cathode tabs 142a, 142b, . . . , 142n are each connected to the collective cathode tab 142 in a parallel connection. As shown, the electrochemical cells 100 are disposed in a casing 160. In some embodiments, each of the electrochemical cells 100 can be placed in an individual casing.

In some embodiments, each of the stacks 1000 can include the electrochemical cells 100 arranged in a stack, a collective anode tab 142, a collective cathode tab 122, a casing 160 including a base and a cover assembly, an optional compliant layer, and an insulation layer. In some embodiments, a plurality of electrochemical cells 100 can be arranged in a plurality of stacks, each stack disposed in a casing 160, the casings 160 stacked on top of each other to form a plurality of stacks. In some embodiments, the collective anode tab 122 and the collective cathode tab 142 may be configured so that multiple electrochemical cells 100 (e.g., an anode current collector or a cathode current collector of each of the electrochemical cells) are in contact with one tab, thereby allowing electrical energy to be communicated to and/or withdrawn from the one or multiple electrochemical cells via the single one of the respective tab(s) coupled thereto.

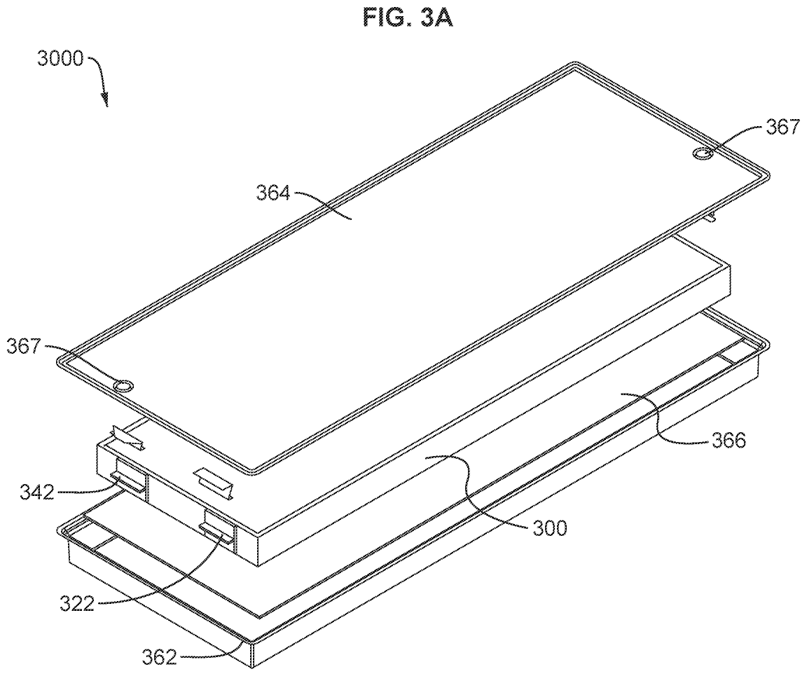

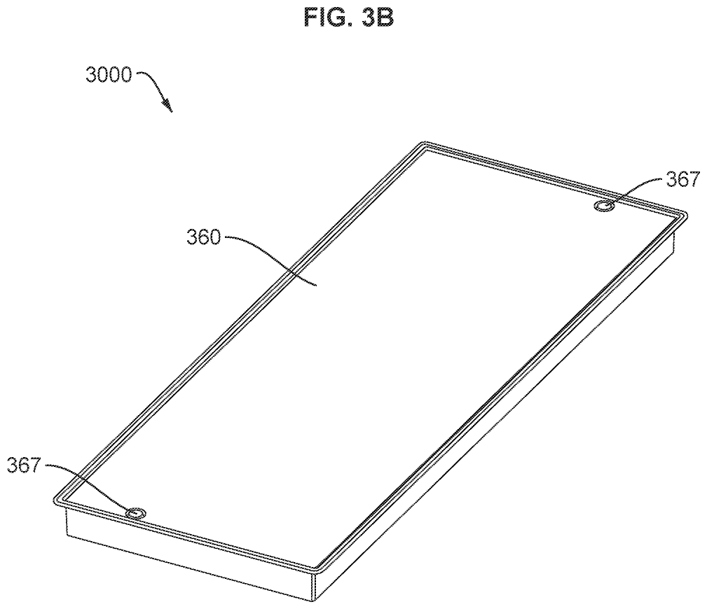

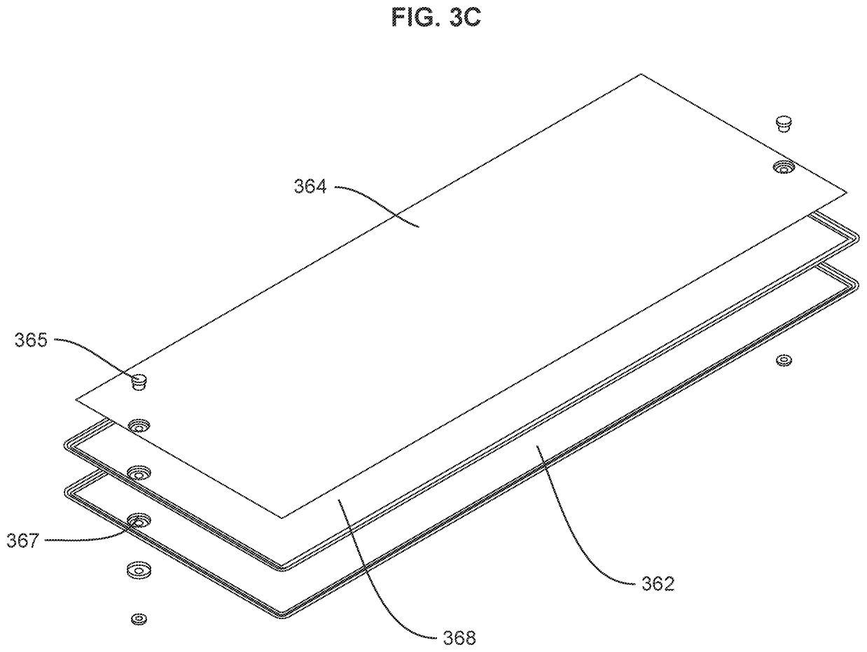

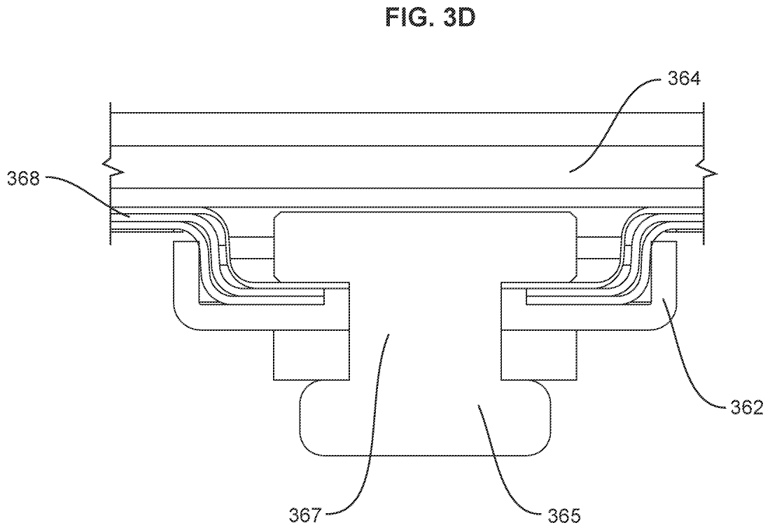

FIGS. 3A-3D show a stack (or a multicell) 3000, according to an embodiment. As shown, the stack 3000 includes electrochemical cells 300 arranged in a stack, a collective anode tab 322, a collective cathode tab 342, a casing 360 including a base 362 and a cover assembly 364, an optional compliant layer 366, and an insulation layer 368. Rivets 365 are fit into rivet holes 367. In some embodiments, the electrochemical cells 300 and the casing 360 can be the same or substantially similar to the electrochemical cells 100 and the casing 160, as described above with reference to FIG. 1-2. Thus, certain aspects of the electrochemical cells 300 and the casing 360 are not described in greater detail herein.

The base 362 and the cover assembly 364 form the casing 360. In some embodiments, the base 362 can be polarized. In some embodiments, the base 362 can be positively polarized or negatively polarized. In some embodiments, the cover assembly 364 can be polarized. In some embodiments, the cover assembly 364 can be positively polarized or negatively polarized. In some embodiments, a depth of the base 362 may correspond to the number of electrochemical cells 300 disposed on the base 362. For example, in some embodiments, the base 362 may be shallow if the base 362 is accommodating a small number of electrochemical cells 300. In some embodiments, the depth of the base 362 may be increased to accommodate a larger number of electrochemical cells 300. In some embodiments, the compliant layer 366 can provide insulation and/or space filler between the electrochemical cells 300 and the base 362. In some embodiments, the compliant layer 366 can be a soft layer that applies a pressure to the electrochemical cells 300 upon being compressed. The insulator 368 can be disposed inside the casing 360 to limit heat transfer within the electrochemical cell stack 3000.

The rivets 365 are inserted through the rivet holes 367 in the cover assembly 364, the insulation 368, and the base 362 to hold the casing 360 together. The rivets 365 can carry electrical current from the electrochemical cells 300 to an external surface of the casing 360. This can facilitate the movement of current from the stack 3000 to another stack. The feedthrough of the rivets 365 can also maintain a hermetic seal in the casing 360. In some embodiments, the feedthrough of the rivets 365 can be press-fit, insert molded, epoxied, or secured via a threaded feature and a backing nut. In some embodiments, the base 362 and/or the cover assembly 364 can function as electroactive terminals, functioning as electrical contact surfaces. In some embodiments, the base 362 and/or the cover assembly 364 can be plated with a low-resistance metal for enhanced conductivity. In some embodiments, a surface of the cover assembly 364 and/or a surface of the base 362 can be treated internally or externally with one or more coatings or treatments, or one or more coatings may be disposed on one or more surfaces of the cover assembly, for example, to increase the conductivity of the surface such that current flow across the surface is increased when in contact with another stack. In some embodiments, the cover assembly 364 and/or the base 362 can include an additional layer and/or surface treatment to improve the number of contact points between stacks. In some embodiments the additional layer and/or surface treatment may include, for example, a soft and/or deformable layer, an expanded metal mesh layer, a plated layer (e.g., electroplated layer), a conductive epoxy a surface roughing treatment, a surface flatness treatment, or any treatment, coating, or layer configured to improve connection areas or points (i.e., reducing the resistance of a compression connection), or any suitable combination thereof. In some embodiments, the additional layer can include semisolid slurries with high electronic conductivities and binding capabilities. In some embodiments, the semisolid slurries may include a silicon oil-based liquid to enhance the safety of connection (e.g., to prevent short circuit). In some embodiments, the stacks can be coupled with fastener screws, conductive polymer with adhesives coatings, and/or UV-curved polymer bonded, any other suitable fastening mechanism or any suitable combination thereof. In some embodiments, the base 362 and/or the cover assembly 364 can include raised geometry or features (e.g., dimples, detents, pins, projections, etc.) for enhanced contact resistance.

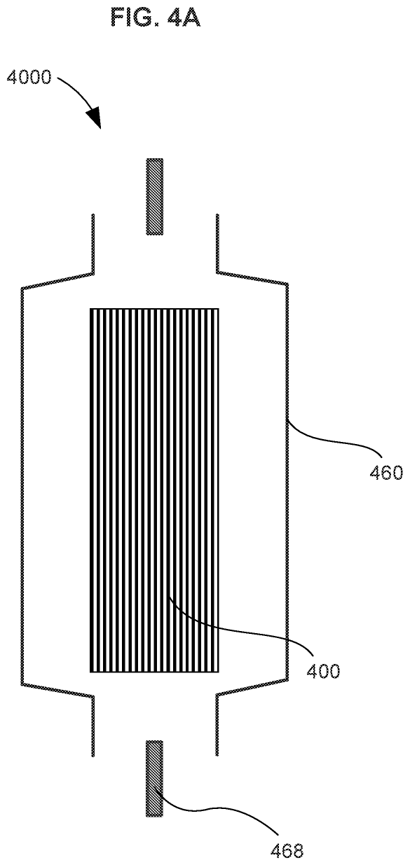

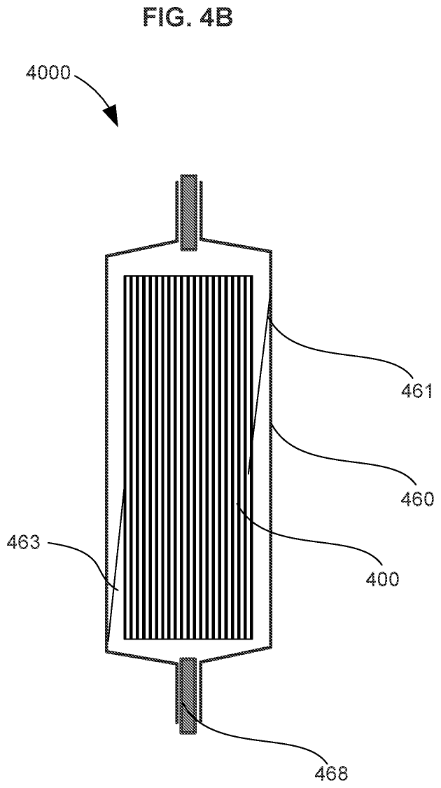

FIGS. 4A-4B are illustrations of stack (or multicell) 4000, according to an embodiment. As shown, the stack 4000 includes electrochemical cells 400, casing 460, an anode connector 461, a cathode connector 463, and insulation 468. In some embodiments, the electrochemical cells 400, the casing 460, and the insulation 468 can be the same or substantially similar to the electrochemical cells 300, the casing 360, and the insulation 368, as described above with reference to FIGS. 3A-3D. Thus, certain aspects of the electrochemical cells 400, the casing 460, and the insulation 468 are not described in greater detail herein.

The anode connector 461 is electrically connected to each of the anodes in the electrochemical cells 400 via the anode tabs and carries electrical current to the external surface of the casing 460. The cathode connector 463 is electrically connected to each of the cathodes in the electrochemical cells 400 via the cathode tabs and carries electrical current to the external surface of the casing 460 on an opposite side from the anode connector 461. Including an anode connector and a cathode connector enables stacking of polarized plates. In some embodiments, the casing 460 can be metal (e.g., stamped), film (metal foil or laminated metal/polymer composite), molded/formed plastic with a conductive layer (e.g., metallization, insert molded plate), and any combination thereof. In some embodiments, the insulator 468 can extend around an outside perimeter of the electrochemical cell stack 4000.

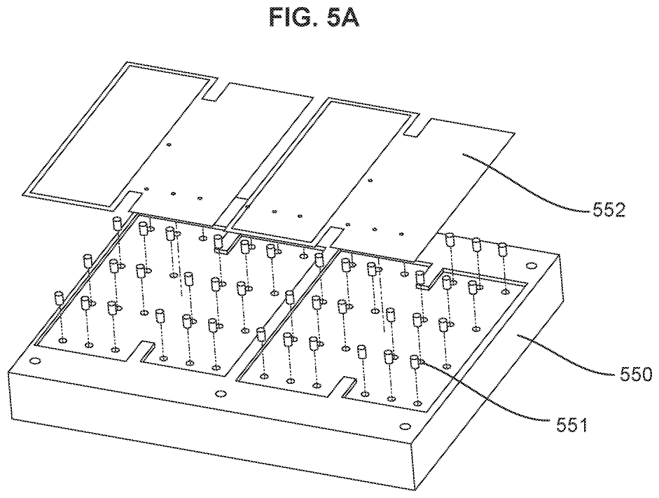

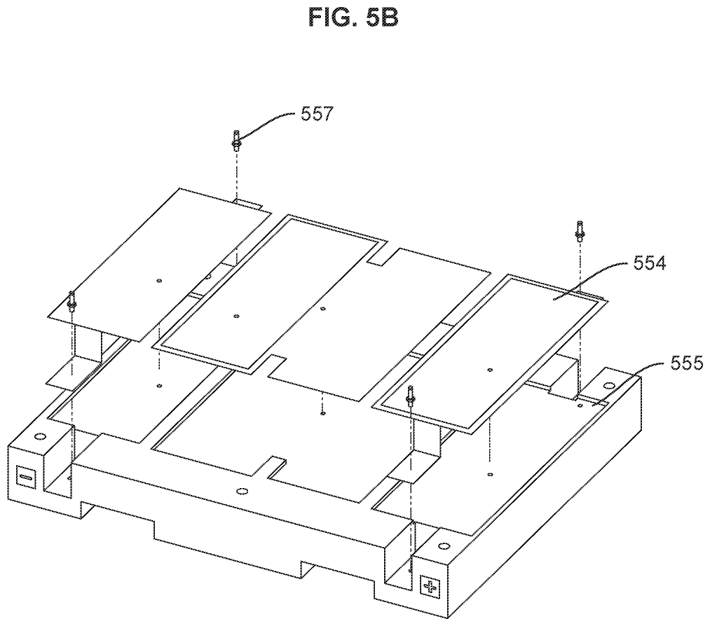

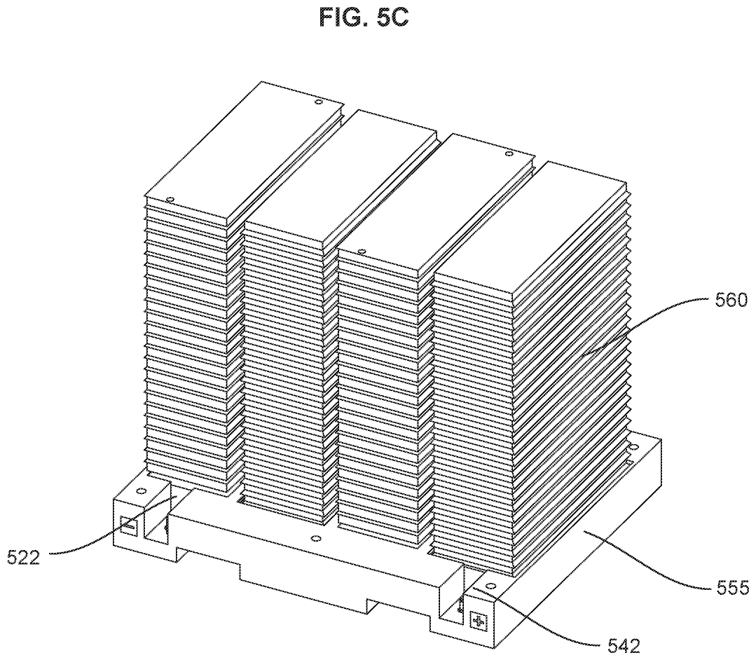

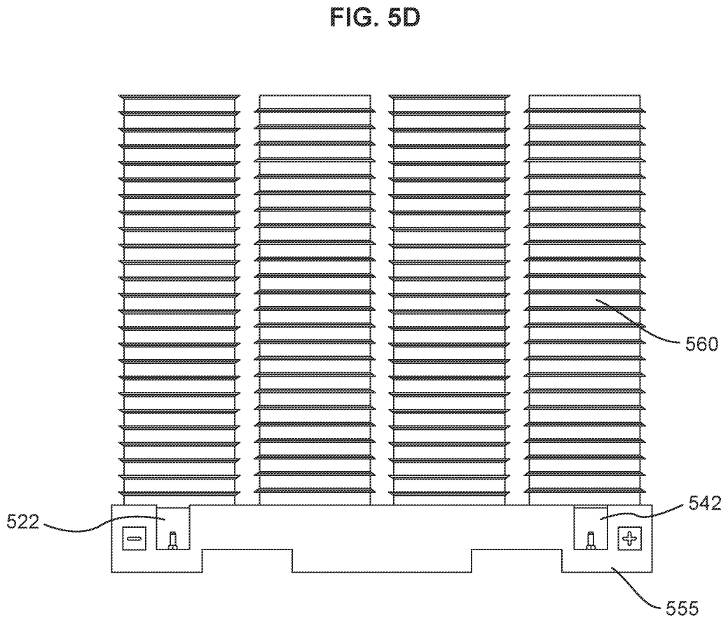

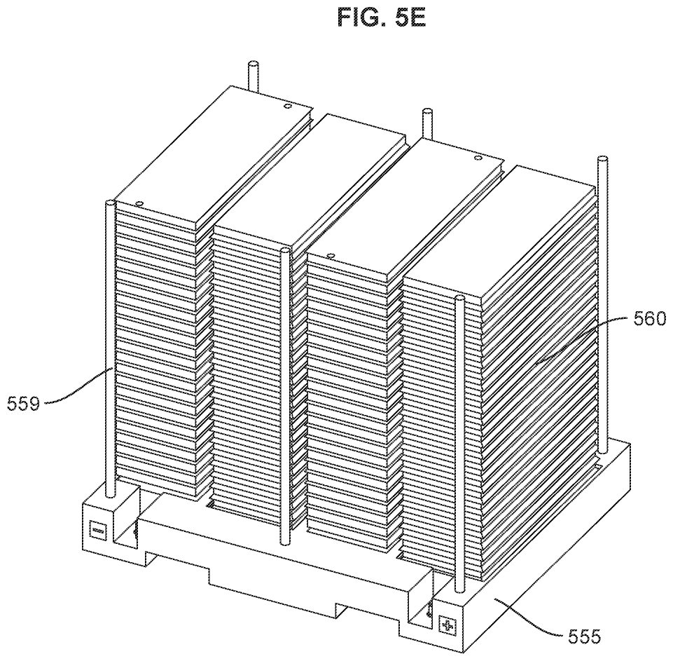

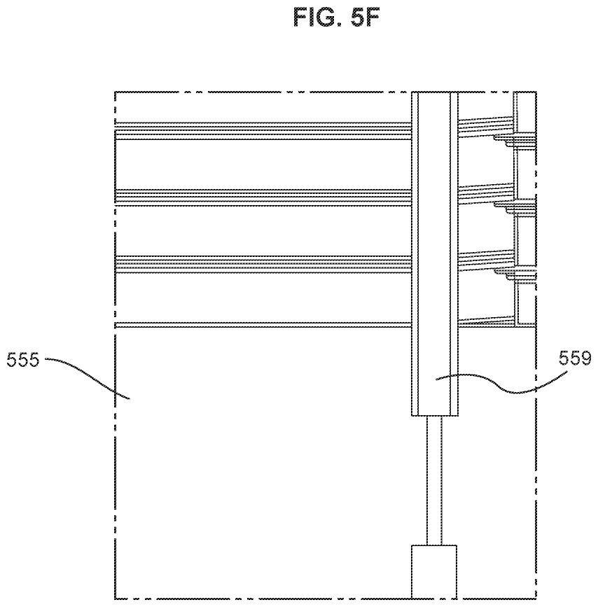

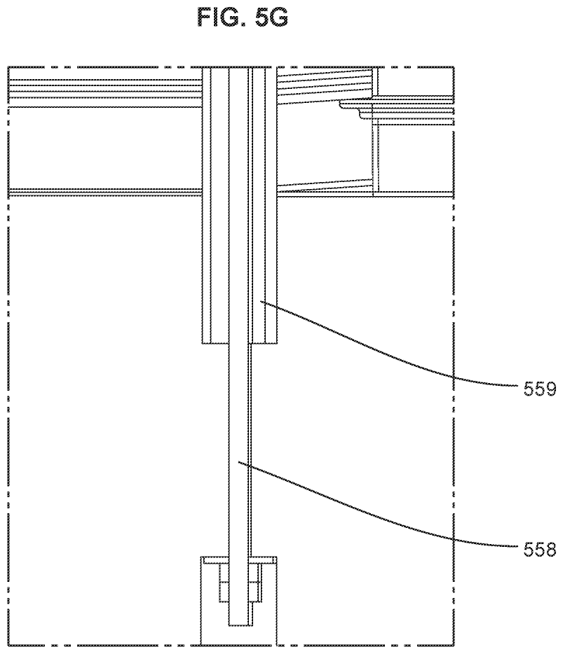

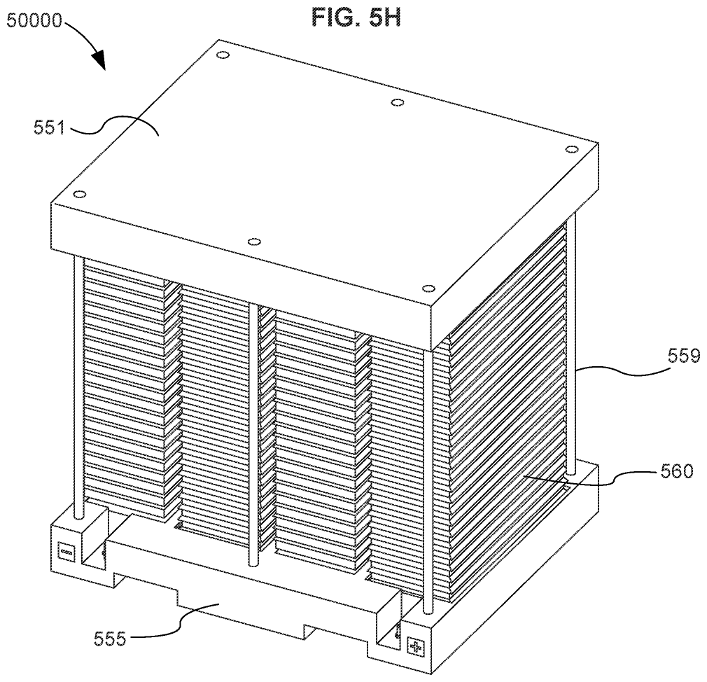

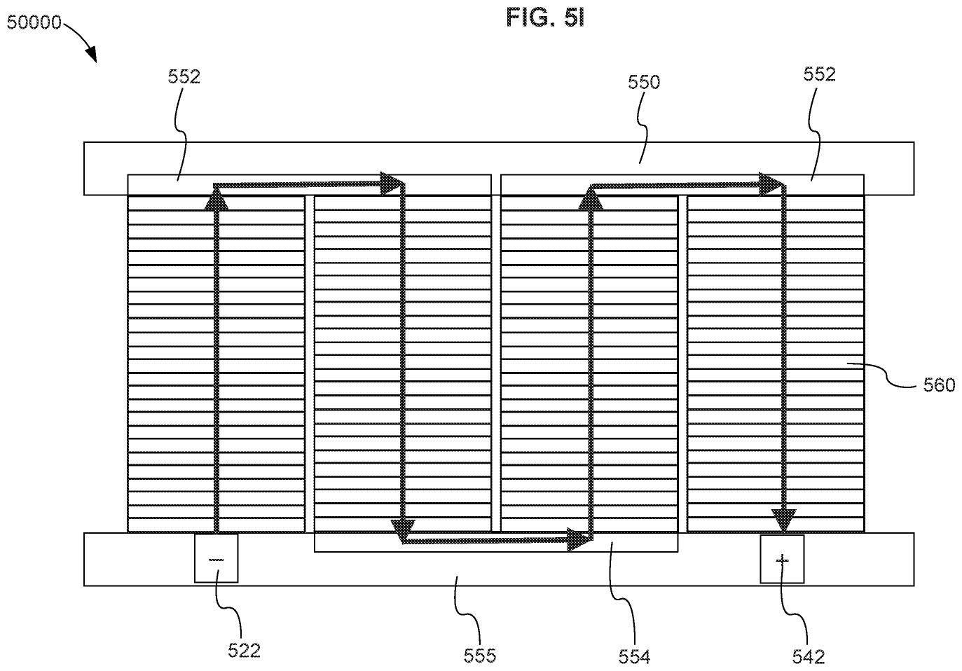

FIGS. 5A-5I show a multicell 50000 with multiple electrochemical cells, and the construction thereof, according to an embodiment. Stackable connections shown in the multicell 50000 can reduce the component count at a system level (e.g., bus bars are not necessary). Additionally, welding equipment can be excluded from the production process (e.g., laser or ultrasonic welders) although the use of a welded connection is envisaged in the scope of this patent. The multicell 50000 can be assembled in the field. This eases the replacement in the event of a failed cell or string since the multicell 50000 includes few or no permanent welded connections. FIG. 5A shows a top pallet 550 with springs 551 being coupled to conductive plates 552. The springs 551 apply a pressure to the conductive plates 552 and create a stack pressure in the multicell 50000. As shown, the springs 551 provide a mechanical connection or interface to the top pallet 550. The springs 551 may apply a defined pressure profile to the conductive plates 552 and/or other components included in and/or coupled to the multicell 50000, for example, bus bars. The springs 551 may include, but are not limited to coil-type springs, flat springs, leaf-type springs, helical spring, Belleville springs, cantilever spring, or other specific biasing or spring device(s). In some embodiments, the springs 551 may be replaced with or used in combination with compressible materials such as, for example, elastomers, rubber, foam, and/or other compressible material or combination thereof that can apply a biasing force on the conductive plate 552 or any other part of the multicell 50000.

As shown, the top pallet 550 includes 48 springs 551. In some embodiments, the top pallet 550 can include at least about 1, at least about 2, at least about 3, at least about 4, at least about 5, at least about 6, at least about 7, at least about 8, at least about 9, at least about 10, at least about at least about 20, at least about 30, at least about 40, at least about 50, at least about 60, at least about 70, at least about 80, at least about 90, at least about 100, at least about 200, at least about 300, at least about 400, at least about 500, at least about 600, at least about 700, at least about 800, or at least about 900 springs 551. In some embodiments, the top pallet 550 can include no more than about 1,000, no more than about 900, no more than about 800, no more than about 700, no more than about 600, no more than about 500, no more than about 400, no more than about 300, no more than about 200, no more than about 100, no more than about 90, no more than about 80, no more than about 70, no more than about 60, no more than about 50, no more than about 40, no more than about 30, no more than about 20, no more than about 10, no more than about 9, no more than about 8, no more than about 7, no more than about 6, no more than about 5, no more than about 4, no more than about 3, or no more than about 2 springs 551. Combinations of the above-referenced numbers of springs 551 are also possible (e.g., at least about 2 and no more than about 1,000 or at least about 30 and no more than about 100), inclusive of all values and ranges therebetween. In some embodiments, the top pallet 550 can include about 1, about 2, about 3, about 4, about 5, about 6, about 7, about 8, about 9, about 10, about 10, about 20, about 30, about about 50, about 60, about 70, about 80, about 90, about 100, about 200, about 300, about 400, about 500, about 600, about 700, about 800, about 900, or about 1,000 springs 551.

The springs 551 contact and press the conductive plates 552 onto the electrochemical cells to provide a pressure. The conductive plates 552 can electrically connect electrochemical cells in series or in parallel. In some embodiments, the conductive plates 552 can have one or more sections. As shown, the conductive plates 552 can have a first section and a second section. Each section may be in contact with a terminal end of a stack. In some embodiments, the conductive plates 552 can have about 2, about 3, about 4, about 5, about 6, about 7, about 8, about 9, about about 15, about 20, about 25, about 30, about 35, about 40, about 45, about 50, about 55, about about 65, about 70, about 75, about 80, about 85, about 90, about 95, or about 100 sections, inclusive of all values and ranges therebetween. In some embodiments, the conductive plates 552 can include integrated spring features in place of standalone springs (e.g., stamped dimples or spring fingers). In some embodiments, the conductive plates 552 can be plated for reduced contact resistance and enhanced corrosion resistance. Raised geometry (e.g., dimples) may be used for reduced contact resistance. Conductor pads and springs can be pre-assembled or otherwise held captive in pallets to comprise single assemblies for ease of a system build.

As shown, the top pallet 550 contacts two conductive plates 552. In some embodiments, the multicell 50000 can include at least about 1, at least about 2, at least about 3, at least about 4, at least about 5, at least about 6, at least about 7, at least about 8, at least about 9, at least about 10, at least about 15, at least about 20, at least about 25, at least about 30, at least about 35, at least about 40, or at least about 45 conductive plates 552. In some embodiments, the multicell 5000 can include no more than about 50, no more than about 45, no more than about 40, no more than about no more than about 30, no more than about 25, no more than about 20, no more than about 15, no more than about 10, no more than about 9, no more than about 8, no more than about 7, no more than about 6, no more than about 5, no more than about 4, no more than about 3, or no more than about 2 conductive plates 552. Combinations of the above-referenced numbers of conductive plates 552 are also possible (e.g., at least about 1 and no more than about 50 or at least about 2 and no more than about 30), inclusive of all values and ranges therebetween. In some embodiments, the multicell 50000 can include about 1, about 2, about 3, about 4, about 5, about 6, about 7, about 8, about 9, about 10, about 15, about 20, about 25, about 30, about 35, about 40, about 45, or about conductive plates 552.

FIG. 5B shows a bottom pallet 555 contacting conductive plates 554. The top pallet 550 and the bottom pallet 555 are used to align the electrochemical cells and provide a means of applying a pressure to large cell surfaces. The conductive plates 554 are coupled to the bottom pallet 555 via system connectors 557. The system connectors 557 can protrude to the outside of the bottom pallet 555 via a positive terminal 542 and a negative terminal 522 and electrically connect the multicell 50000 to another multicell.

As shown, the bottom pallet 555 includes 3 conductive plates 554. In some embodiments, the conductive plates 554 can have one or more sections. As shown, two conductive plates 554 have a first section and one conductive plate 554 has a first section and a second section. Each section may be in contact with a terminal end of a stack. In some embodiments, the conductive plates 554 can have about 2, about 3, about 4, about 5, about 6, about 7, about 8, about 9, about about 15, about 20, about 25, about 30, about 35, about 40, about 45, about 50, about 55, about about 65, about 70, about 75, about 80, about 85, about 90, about 95, or about 100 sections, inclusive of all values and ranges therebetween. In some embodiments, the multicell 50000 can include at least about 1, at least about 2, at least about 3, at least about 4, at least about 5, at least about 6, at least about 7, at least about 8, at least about 9, at least about 10, at least about 15, at least about 20, at least about 25, at least about 30, at least about 35, at least about 40, or at least about 45 conductive plates 554. In some embodiments, the multicell 50000 can include no more than about 50, no more than about 45, no more than about 40, no more than about 35, no more than about 30, no more than about 25, no more than about 20, no more than about 15, no more than about 10, no more than about 9, no more than about 8, no more than about 7, no more than about 6, no more than about 5, no more than about 4, no more than about 3, or no more than about 2 conductive plates 554. Combinations of the above-referenced numbers of conductive plates 554 are also possible (e.g., at least about 1 and no more than about 50 or at least about 2 and no more than about 30), inclusive of all values and ranges therebetween. In some embodiments, the multicell 5000 can include about 1, about 2, about 3, about 4, about 5, about 6, about 7, about 8, about 9, about 10, about 15, about 20, about 25, about 30, about 35, about 40, about 45, or about conductive plates 554.

FIGS. 5C-5D show a plurality of casings 560 stacked on top of the bottom pallet 555. The electrochemical cells are included in casings 560. In some embodiments, the casings 560 can include electrochemical cells individually contained in the casings 560. In some embodiments, the casings 560 can be the same or substantially similar to the casing 360, as described above with reference to FIGS. 3A-3D. Thus, certain aspects of the casings 560 are not described in greater detail herein. In some embodiments, multiple electrochemical cells can be individually contained in the casings 560. In some embodiments, each of the casings 560 can include about 1, about 2, about 3, about 4, about 5, about 6, about 7, about 8, about 9, about 10, about 15, about 20, about about 30, about 35, about 40, about 45, or about 50 electrochemical cells contained therein, inclusive of all values and ranges therebetween.

As shown, the casings 560 are arranged in four stacks with 25 casings 560 in each stack. In some embodiments, the casings 560 can be arranged in m stacks with n casings 560 in each stack, where m and n are positive integers. In some embodiments, m and/or n can be at least about 2, at least about 3, at least about 4, at least about 5, at least about 6, at least about 7, at least about 8, at least about 9, at least about 10, at least about 15, at least about 20, at least about 25, at least about 30, at least about 35, at least about 40, at least about 45, at least about 50, at least about 55, at least about 60, at least about 65, at least about 70, at least about 75, at least about 80, at least about 85, at least about 90, or at least about 95. In some embodiments, m and/or n can be no more than about 100, no more than about 95, no more than about 90, no more than about 85, no more than about 80, no more than about 75, no more than about 70, no more than about 65, no more than about 60, no more than about 55, no more than about 50, no more than about 45, no more than about 40, no more than about 35, no more than about 30, no more than about 25, no more than about 20, no more than about 15, no more than about 10, no more than about 9, no more than about 8, no more than about 7, no more than about 6, no more than about 5, no more than about 4, or no more than about 3. The positive terminal 542 and the negative terminal 522 act as leads for electrical connections to another multicell.

FIGS. 5E-5G show tie rods 559 and hard stops 558 incorporated into the multicell 5000. The tie rods 559 couple the top pallet 550 and the bottom pallet 555. The tie rods 559 can aid in applying a pressure to the stacks of casings 560 and the electrochemical cells therein. The hard stops 558 control a distance between the top pallet 550 and the bottom pallet 555. In some embodiments, the hard stops 558 insulate the tie rods 559 and prevent corrosion or decomposition of the tie rods 559. The tie rods 559 may secure the stacks between the top pallet 550 and the bottom pallet 555 to form the multicell 50000 without welding components, thereby eliminating the need of welding equipment (e.g., laser or ultrasonic welders). Utilizing the tie rods 559 to secure the multicells 50000 also allows for ease of replacement of any number of electrochemical cells in a stack in the event of a failed electrochemical cell or string of electrochemical cells because there are no permanent welded connections.

FIG. 5I shows movement of current through multiple stacks of electrochemical cells in the multicell 50000. Current flows from the negative terminal 522 via a first stack of casings 560 and electrochemical cells to a first conductive plate 552 contacting the top pallet 550. The current then passes through a second stack of casings 560 and electrochemical cells to a conductive plate 554 contacting the bottom pallet 555. The current then passes through a third stack of casings 560 and electrochemical cells to a second conductive plate 552 and then through a fourth stack of casings 560 and electrochemical cells to the positive terminal 542.

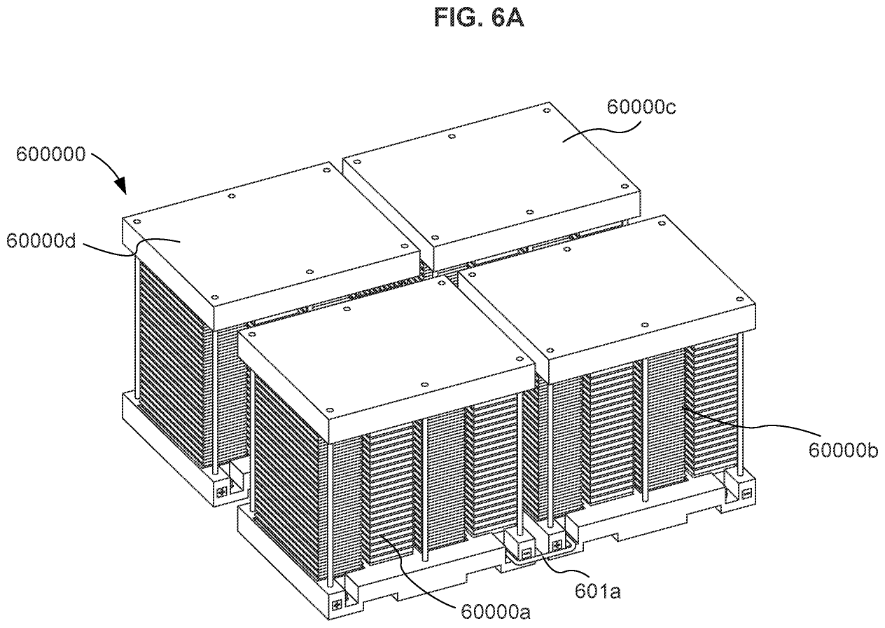

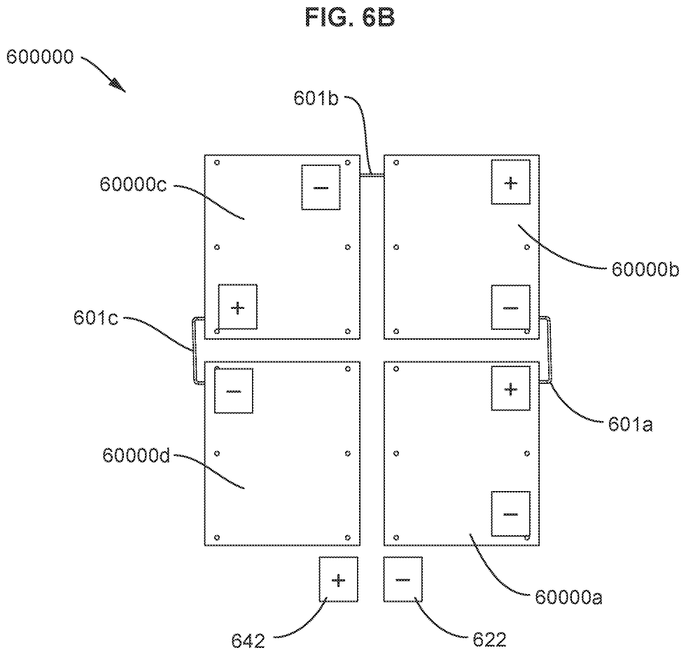

FIGS. 6A-6B shows an apparatus 600000 with multiple multicells 60000a, 60000b, 60000c, 60000d (collectively referred to as multicells 60000), according to an embodiment. In some embodiments, the multicells 60000 can be the same or substantially similar to the multicell 10000, as described above with reference to FIG. 1. Thus, certain aspects of the multicells 60000 are not described in greater detail herein. As shown, the multicell 60000a is electrically connected to the multicell 60000b via a string connection 601a, the multicell 60000b is electrically connected to the multicell 60000c via a string connection 601b, and the multicell 60000c is electrically connected to the multicell 60000d via a string connection 601c. The string connections 601a, 601b, 601c (collectively referred to as string connections 601) can be composed of an electrically conductive material. The apparatus includes a collective negative terminal 622 and a collective positive terminal 642 for connections to a voltage source. In some embodiments, the string connections 601 can be composed of a metal (e.g., copper, aluminum, gold, silver, nickel, iron, stainless steel, iron, titanium, steel, or any combination thereof). In some embodiments, the string connections 601 can be composed of one or more electrically conductive polymers.

As shown, the apparatus 600000 includes four multicells 60000. In some embodiments, the apparatus 600000 can include at least about 2, at least about 3, at least about 4, at least about at least about 6, at least about 7, at least about 8, at least about 9, at least about 10, at least about at least about 30, at least about 40, at least about 50, at least about 60, at least about 70, at least about 80, at least about 90, at least about 100, at least about 200, at least about 300, at least about 400, at least about 500, at least about 600, at least about 700, at least about 800, or at least about 900 multicells 60000. In some embodiments, the apparatus 600000 can include no more than about 1,000, no more than about 900, no more than about 800, no more than about 700, no more than about 600, no more than about 500, no more than about 400, no more than about 300, no more than about 200, no more than about 100, no more than about 90, no more than about 80, no more than about 70, no more than about 60, no more than about 50, no more than about 40, no more than about 30, no more than about 20, no more than about 10, no more than about 9, no more than about 8, no more than about 7, no more than about 6, no more than about 5, no more than about 4, no more than about 3 multicells 60000. Combinations of the above-referenced numbers of multicells 60000 are also possible (e.g., at least about 2 and no more than about 1,000 or at least about 4 and no more than about 50), inclusive of all values and ranges therebetween. In some embodiments, the apparatus 600000 can include about 2, about 3, about 4, about 5, about 6, about 7, about 8, about 9, about 10, about 20, about 30, about 40, about 50, about 60, about 70, about 80, about 90, about 100, about 200, about 300, about 400, about 500, about 600, about 700, about 800, about 900, or about 1,000 multicells 60000.

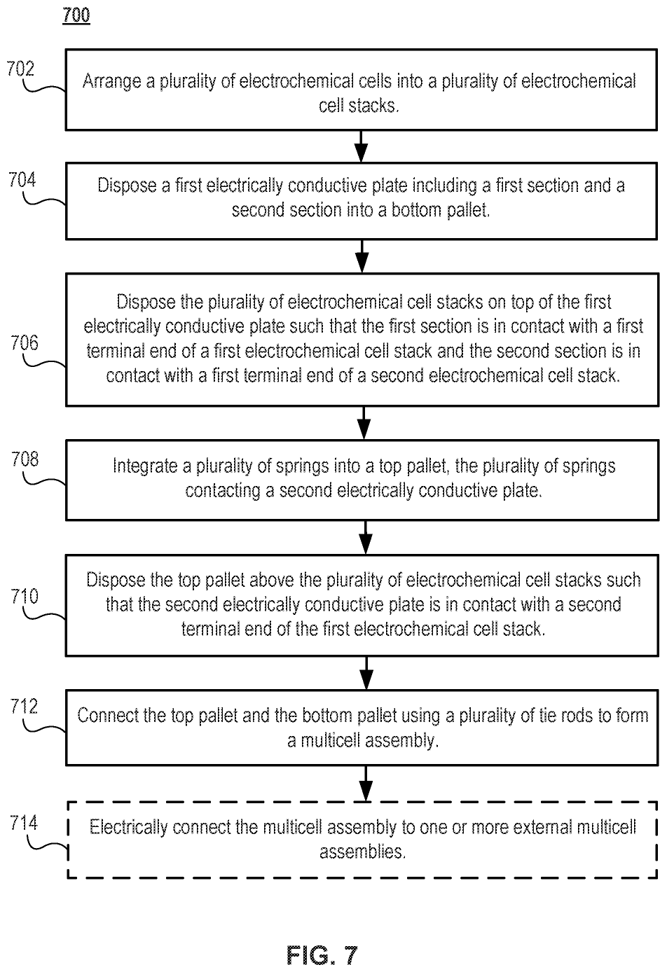

FIG. 7 is a schematic flow chart of a method 700 for arranging electrochemical cells and multicells in stacks as part of a module build. While described with respect to the electrochemical cells 100, stacks 1000, multicells 10000, and apparatus 100000, the method 700 is equally applicable to any electrochemical cell, stack, multicell, and apparatus described herein. All such variations should be considered to be within the scope of this disclosure.

The method 700 includes arranging a plurality of electrochemical cells 100 into a plurality of stacks 1000, at step 702. At step 704, a first conductive plate 154 including a first section and a second section is disposed onto a bottom pallet 155. At step 706, the plurality of stacks 1000 can be disposed on top of the first conductive plate 154 such that the first section is in contact with a first terminal end of a first stack 1000a, 1000b, . . . , 1000n and a second section is in contact with a first terminal end of a second stack 1000a, 1000b, . . . , 1000n. In some embodiments, the plurality of stacks 1000 can be disposed on top of one or more conductive plates 154, each conductive plate 154 having one or more sections. In such embodiments, each section of each conductive plate 154 can be in contact with a terminal end of a stack 1000a, 1000b, . . . , 1000n. At step 708, a biasing member such as a plurality of springs 151 can be integrated into a top pallet 150, the plurality of springs 151 contacting a second conductive plate 152. At step 710, the top pallet 150 is disposed above the stacks 1000 such that the second conductive plate 152 is in contact with a second terminal end of the first stack 1000a, 1000b, . . . , 1000n. In some embodiments, the plurality of springs 151 can be in contact with one or more conductive plates 152, each conductive plate 152 having one or more sections. In such embodiments, each section of each conductive plate 152 can be in contact with a terminal end of a stack 1000a, 1000b, . . . , 1000n. At step 712, the top pallet 150 and the bottom pallet 155 are connected using a plurality of tie rods to form a multicell assembly 10000a, 10000b, . . . , 10000n. At step 714, the multicell assembly 10000a, 10000b, . . . , 10000n may optionally be electrically connected to one or more external multicell assemblies 10000. Electrically connecting multiple multicell assemblies 10000 enables formation of a high voltage apparatus that may be used in high power applications.

Various concepts may be embodied as one or more methods, of which at least one example has been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments. Put differently, it is to be understood that such features may not necessarily be limited to a particular order of execution, but rather, any number of threads, processes, services, servers, and/or the like that may execute serially, asynchronously, concurrently, in parallel, simultaneously, synchronously, and/or the like in a manner consistent with the disclosure. As such, some of these features may be mutually contradictory, in that they cannot be simultaneously present in a single embodiment. Similarly, some features are applicable to one aspect of the innovations, and inapplicable to others.

In addition, the disclosure may include other innovations not presently described. Applicant reserves all rights in such innovations, including the right to embodiment such innovations, file additional applications, continuations, continuations-in-part, divisional s, and/or the like thereof. As such, it should be understood that advantages, embodiments, examples, functional, features, logical, operational, organizational, structural, topological, and/or other aspects of the disclosure are not to be considered limitations on the disclosure as defined by the embodiments or limitations on equivalents to the embodiments. Depending on the particular desires and/or characteristics of an individual and/or enterprise user, database configuration and/or relational model, data type, data transmission and/or network framework, syntax structure, and/or the like, various embodiments of the technology disclosed herein may be implemented in a manner that enables a great deal of flexibility and customization as described herein.

All definitions, as defined and used herein, should be understood to control over dictionary definitions, definitions in documents incorporated by reference, and/or ordinary meanings of the defined terms.

As used herein, in particular embodiments, the terms “about” or “approximately” when preceding a numerical value indicates the value plus or minus a range of 10%. Where a range of values is provided, it is understood that each intervening value, to the tenth of the unit of the lower limit unless the context clearly dictates otherwise, between the upper and lower limit of that range and any other stated or intervening value in that stated range is encompassed within the disclosure. That the upper and lower limits of these smaller ranges can independently be included in the smaller ranges is also encompassed within the disclosure, subject to any specifically excluded limit in the stated range. Where the stated range includes one or both of the limits, ranges excluding either or both of those included limits are also included in the disclosure.

The phrase “and/or,” as used herein in the specification and in the embodiments, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used herein in the specification and in the embodiments, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the embodiments, “consisting of,” will refer to the inclusion of exactly one element of a number or list of elements. In general, the term “or” as used herein shall only be interpreted as indicating exclusive alternatives (i.e., “one or the other but not both”) when preceded by terms of exclusivity, such as “either,” “one of” “only one of” or “exactly one of.” “Consisting essentially of,” when used in the embodiments, shall have its ordinary meaning as used in the field of patent law.

As used herein in the specification and in the embodiments, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

In the embodiments, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03.

While specific embodiments of the present disclosure have been outlined above, many alternatives, modifications, and variations will be apparent to those skilled in the art. Accordingly, the embodiments set forth herein are intended to be illustrative, not limiting. Various changes may be made without departing from the spirit and scope of the disclosure. Where methods and steps described above indicate certain events occurring in a certain order, those of ordinary skill in the art having the benefit of this disclosure would recognize that the ordering of certain steps may be modified and such modification are in accordance with the variations of the invention. Additionally, certain of the steps may be performed concurrently in a parallel process when possible, as well as performed sequentially as described above. The embodiments have been particularly shown and described, but it will be understood that various changes in form and details may be made.

1. An apparatus, comprising:
a plurality of electrochemical cell stacks each including a plurality of electrochemical cells connected in series;
a first electrically conductive plate including a first section and a second section, the first section of the first electrically conductive plate in contact with a first terminal end of a first electrochemical cell stack from the plurality of electrochemical cell stacks, the second section of the first electrically conductive plate in contact with a first terminal end of a second electrochemical cell stack from the plurality of electrochemical cell stacks; and
a second electrically conductive plate in contact with a second terminal end of the first electrochemical cell stack.

2. The apparatus of claim 1, wherein a first section of the second electrically conductive plate is in contact with the second terminal end of the first electrochemical cell stack and the second electrically conductive plate includes a second section in contact with a second terminal end of the second electrochemical cell stack.

3. The apparatus of claim 1, wherein a first section of the second electrically conductive plate is in contact with the second terminal end of the first electrochemical cell stack and the second electrically conductive plate includes a second section in contact with a first terminal end of a third electrochemical cell stack.

4. The apparatus of claim 3, further comprising:
a third electrically conductive plate including a first and second section, the first section of the third electrically conductive plate in contact with a second terminal end of the third electrochemical cell stack and the second section of the third electrically conductive plate in contact with a first terminal end of a fourth electrochemical cell stack.

5. The apparatus of claim 1, further comprising:
a top pallet disposed on top of the plurality of electrochemical cell stacks; and
a bottom pallet disposed below the plurality of electrochemical cell stacks.

6. The apparatus of claim 5, further comprising:
a plurality of springs integrated into the top pallet, the plurality of springs contacting the second electrically conductive plates and configured to apply a pressure to the plurality of electrochemical cell stacks.

7. The apparatus of claim 5, further comprising:
a plurality of tie rods connecting the top pallet and the bottom pallet.

8. The apparatus of claim 7, wherein the plurality of tie rods are each encircled by a hard stop, the hard stop configured to control a distance between the top pallet and the bottom pallet and to electrically insulate the tie rods and protect the tie rods from corrosion.

9. The apparatus of claim 8, wherein the plurality of electrochemical cell stacks is a first plurality of electrochemical cell stacks, the apparatus further comprising:
a second plurality of electrochemical cell stacks; and
a connector electrically coupling the first plurality of electrochemical cell stacks to the second plurality of electrochemical cell stacks.

10. An apparatus, comprising:
a plurality of electrochemical cell stacks, each electrochemical cell stack from the plurality of electrochemical cell stacks including a plurality of electrochemical cells connected in series;
a first electrically conductive plate configured to electrically connect a first pair of electrochemical cell stacks from the plurality of electrochemical cell stacks in series; and
a second electrically conductive plate configured to electrically connect a second pair of electrochemical cell stacks from the plurality of electrochemical cell stacks in series.

11. The apparatus of claim 10, wherein the first pair of electrochemical cell stacks has one electrochemical cell stack in common with the second pair of electrochemical cell stacks.

12. The apparatus of claim 11, wherein the first electrically conductive plate includes a first section in electrical contact with a first terminal end of a first electrochemical cell stack from the plurality of electrochemical cell stacks and a second section in electrical contact with a first terminal end of a second electrochemical cell stack, and wherein the second electrically conductive plate includes a first section in electrical contact with a second terminal end of the first electrochemical cell stack and a second section in electrical contact with a first terminal end of a third electrochemical cell.

13. The apparatus of claim 12, further comprising:
a third electrically conductive plate including a first section and a second section, the first section of the third electrically conductive plate in electrical contact with a second terminal end of the third electrochemical cell stack and the second section of the third electrically conductive plate in electrical contact with a first terminal end of a fourth electrochemical cell stack.

14. The apparatus of claim 10, further comprising:
a top pallet disposed on top of the plurality of electrochemical cell stacks; and
a bottom pallet disposed below the plurality of electrochemical cell stacks.

15. The apparatus of claim 14, further comprising:
a plurality of springs integrated into the top pallet, the plurality of springs contacting at least one of the first electrically conductive plate or the second electrically conductive plate, the plurality of springs configured to apply a pressure to the plurality of electrochemical cell stacks.

16. The apparatus of claim 14, further comprising:
a plurality of tie rods connecting the top pallet and the bottom pallet.

17. The apparatus of claim 16, wherein the plurality of tie rods are each encircled by a hard stop, the hard stop configured to control a distance between the top pallet and the bottom pallet and to electrically insulate the tie rods and protect the tie rods from corrosion.

18. The apparatus of claim 10, wherein the plurality of electrochemical cell stacks is a first plurality of electrochemical cell stacks, the apparatus further comprising:
a second plurality of electrochemical cell stacks; and
a connector electrically coupling the first plurality of electrochemical cell stacks to the second plurality of electrochemical cell stacks.

19. An apparatus, comprising:
a first stack of electrochemical cells connected in series;
a second stack of electrochemical cells connected in series; and
an electrically conductive plate contacting a first electrochemical cell at a terminal end of the first stack of electrochemical cells and a second electrochemical cell at a terminal end of the second stack of electrochemical cells.

20. The apparatus of claim 19, wherein the electrically conductive plate is a first electrically conductive plate and the terminal end of the second electrochemical cell stack is a first terminal end, the apparatus further comprising:
a third stack of electrochemical cells; and
a second electrically conductive plate contacting an electrochemical cell at a second terminal end of the second electrochemical cell stack and an electrochemical cell at a terminal end of the third electrochemical cell stack.

21. The apparatus of claim 20, wherein the terminal end of the third electrochemical cell stack is a first terminal end, the apparatus further comprising:
a fourth stack of electrochemical cells; and
a third electrically conductive plate contacting an electrochemical cell at a second terminal end of the third electrochemical cell stack and an electrochemical cell at a terminal end of the fourth electrochemical cell stack.

22. The apparatus of claim 19, further comprising:
a top pallet disposed on top of the first electrochemical cell stack and the second electrochemical cell stack; and
a bottom pallet disposed below the first electrochemical cell stack and the second electrochemical cell stack.

23. The apparatus of claim 22, further comprising:
a plurality of springs integrated into the top pallet, the plurality of springs contacting the electrically conductive plate and configured to apply a pressure to the first electrochemical cell stack and the second electrochemical cell stack.

24. The apparatus of claim 22, further comprising:
a plurality of tie rods connecting the top pallet and the bottom pallet.

25. The apparatus of claim 24, wherein the plurality of tie rods are each encircled by a hard stop, the hard stop configured to control a distance between the top pallet and the bottom pallet and to electrically insulate the tie rods and protect the tie rods from corrosion.
